(19) United States
(12) Patent Application Publication
(10) Pub. No.: US 2024/0428848 A1
(43) Pub. Date: Dec. 26, 2024

(54) 8-T SRAM BITCELL FOR FPGA PROGRAMMING

(71) Applicant: XILINX, INC., San Jose, CA (US)

(72) Inventors: Nui CHONG, San Jose, CA (US); Jing Jing CHEN, San Jose, CA (US); Babruwahan Tulshiram GADE, Hyderabad (IN); Shidong ZHOU, Hyderabad (IN)

(21) Appl. No.: 18/213,647

(22) Filed: Jun. 23, 2023

(51) Int. Cl. G11C 11/4093; G11C 11/4099

(52) U.S. Cl. CPC G11C 11/4093; G11C 11/4099

(57) ABSTRACT

A memory device includes a first bit cell comprising a first inverter, the first inverter comprising a p-type transistor coupled to an n-type transistor, and header circuitry coupled to the first inverter and comprising a first header transistor and a second header transistor, the first header transistor having a gate configured to receive a bias voltage, the second header transistor having a gate configured to receive a reference voltage.

### TECHNICAL FIELD

Examples of the present disclosure generally relate to memory cells for an integrated circuitry (IC) device.

### BACKGROUND

Memory cells for integrated circuitry devices (ICs) have many requirements and limitations that are different from those for other types of memory cells, such as those for static random access memory (SRAM). Some IC devices utilize an embedded SRAM called a configuration random access memory (CRAM), For example the IC device may be a field programmable gate array (FPGA). For example, while the storage nodes of conventional SRAM memory only interact with the word or address line and the data lines of the memory cell array, the storage nodes of CRAM memory cells are used to directly connect to neighboring circuitry in order to configure the logic of the FPGA. CRAM consists of SRAM and is used to configure all of the user logic in an FPGA.

### SUMMARY

In one or more examples, a memory device includes a first bit cell comprising a first inverter, the first inverter comprising a p-type transistor coupled to an n-type transistor, and header circuitry coupled to the first inverter and comprising a first header transistor and a second header transistor, the first header transistor having a gate configured to receive a bias voltage, the second header transistor having a gate configured to receive a reference voltage.

In one or more examples, a memory device includes first header circuitry comprising a first header transistor and a second header transistor, the first header transistor having a gate configured to receive a bias voltage, the second header transistor having a gate configured to receive a reference voltage, second header circuitry comprising a third header transistor and a fourth header transistor, the third header transistor having a gate configured to receive the bias voltage, the fourth header transistor having a gate configured to receive the reference voltage, a first bit cell and a second bit cell coupled to the first header circuitry; and a third bit cell and a fourth bit cell coupled to the second header circuitry.

In one or more examples, a memory device includes a first bit cell comprising a first inverter cross-coupled to a second inverter by a first storage node and a first inverse storage node; and a first header circuitry comprising a first header transistor and a second header transistor; the first header transistor having a gate configured to receive a bias voltage, the second header transistor having a gate configured to receive a reference voltage, the first header circuitry coupled to the first inverter and the second inverter.

### BRIEF DESCRIPTION OF DRAWINGS

FIG. 1 illustrates a block diagram of an integrated circuit (IC) according to one or more examples.

FIG. 2 illustrates a configurable logic block (CLB) according to one or more examples.

FIG. 3 illustrates a configured random access memory (CRAM) device according to one or more examples.

FIG. 4 illustrates a CRAM device according to one or more examples.

FIG. 5 illustrates a schematic implementation of a CRAM device according to one or more examples.

FIG. 6 illustrates a schematic implementation of a CRAM device according to one or more examples.

FIG. 7 illustrates a schematic implementation of a CRAM device according to one or more examples.

### DETAILED DESCRIPTION

Typically integrated circuitry devices (ICs) use an embedded static random access memory (SRAM) called a configuration random access memory (CRAM). CRAM memory cells are directly connected to and control a corresponding IC, such as a field programmable gate array (FPGA). Each bit cell of a CRAM memory cell requires: a compact layout for area scaling, direct access connections to internal storage nodes of FPGA logic, a large write margin, and low bitline and cell leakage in order to meet the requirements of advanced technology beyond the 7 nm field-effect transistor (FinFET) technology node (i.e., the 7 nm node). However, once passing the 7 nm node, conventional 6-T CRAM memory cell performance degrades. The node-to-node technology transistor performance gain slows down. Additionally, during the write operation the read and write operations are fighting. Therefore, to maintain a larger write margin, in conventional 6-T memory cells, weaker pull-up (p-type) transistors are used. However as a memory cell is scaled down to meet the constraints required by advanced technology beyond the 7 nm node, although the dimensions of the memory cell are scaled, the bitline and cell leakage are not. For example, every CRAM memory cell has a reverification built-in which causes current leakage. During a write operation if too much leakage is present, the bitline current will converge to ground so it cannot be read.

Furthermore, the requirements of advanced technology beyond the 7 nm node and the highly restricted layout of memory cell rules disallow the narrowest and weakest pull-up (p-type) transistors to be used. Therefore, the pass-gate (n-type) transistors need to be much wider to maintain a high alpha ratio between the pull-up and pass-gate transistors, and write margin. Wider and/or stronger pass-gate transistors would maintain the alpha ratio between the pull-up transistors and the pass-gate transistors. However, a wider/stronger pass-gate transistor is penalized by high bitline and high cell leakage along with the increased area because, as mentioned above, the leakages do not scale. Lastly, CRAM Vccmin (minimum Vcc operation voltage) yield loss is more susceptible to soft failures caused by slightly degraded n-type transistors resulting from higher device variation, larger process complexity & soft defect modes in advanced technology beyond the 7 nm node.

Embodiments herein, relate to an 8-T CRAM memory device that includes CRAM bit cells that are coupled to a header circuitry that is coupled to biasing circuitry. The biasing circuitry is controlled to weaken the pull-up transistors without having to widen the pass-gate transistors. Furthermore, the header circuitry is implemented as an additional row of p-type transistors between rows of the pull-up transistors and are shared between bit cells to reduce adding to the overall area of conventional 6-T CRAM cells. Additionally, the bias circuitry can be used to recover soft failures caused due to a degraded n-type transistor.

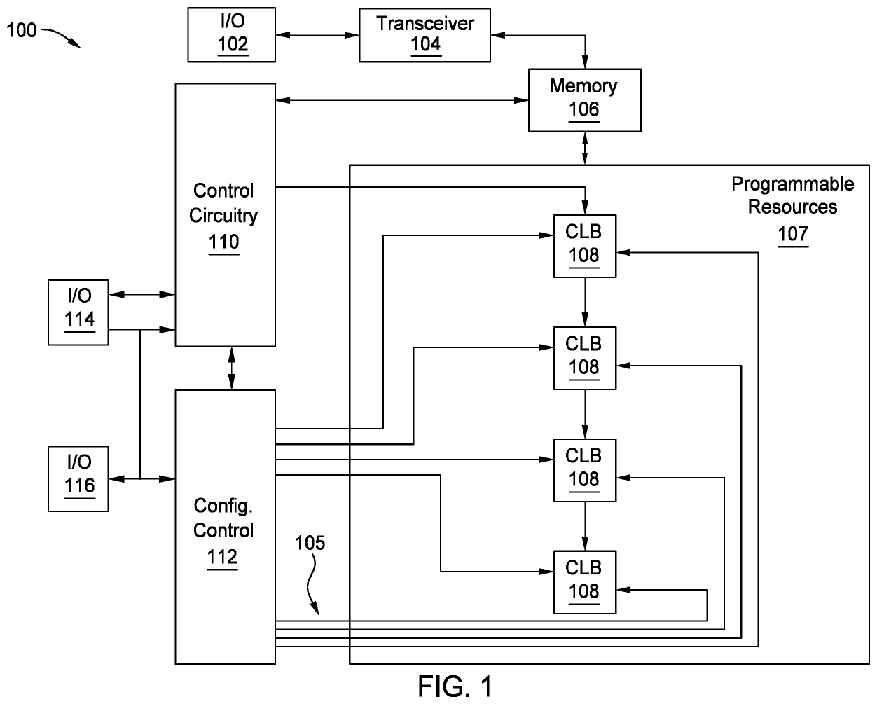

FIG. 1 illustrates a block diagram of an integrated circuit device (IC) 100 according to one or more examples. In one example, an input/output (I/O) port 114 is coupled to a control circuitry 110 that controls programmable resources 107 including configuration memory. The programmable resources 107 are embedded memory circuitries in the IC 100. In one example, the programmable resources 107 is a field programmable gate array (FPGA). In other examples, the programmable resources 107 are other types of programmable devices with an embedded memory device. A configuration controller circuitry 112 provides configuration data to the programmable resources 107. In one example, the configuration data includes a complete file of bits that configure the programmable resources 107. In another example, the configuration data includes a partial bit file to enable partial configuration of the programmable resources 107. The configuration data enables the operation of the programmable resources 107, and includes memory bits comprising configuration bit functioning as control bits provided to the programmable resources 107. A memory 106 is coupled to the control circuitry 110 and the programmable resources 107. A transceiver 104 may be coupled to an I/O port 102, and transmits and receives signals. Other I/O ports may be coupled to circuits of the IC 100, such as I/O port 116 that is coupled to the configuration controller circuitry 112.

The configuration memory associated with the programmable resources 107 are programmed by way of the routing network 105. The routing network 105 enables routing memory bits operating as enable signals to corresponding circuit blocks. In one example, a plurality of configurable logic blocks (CLBs) 108, are coupled to receive global signals from the control circuitry 110. The control circuitry 110 could be used to provide global signals to each CLB 108. In contrast, the routing network 105 enables separately routing a local enable signal to individual CLBs 108. In one example, the local enable signal allows the CLBs 108 that receive the signal to be reconfigured during a partial reconfiguration.

In other examples, the programmable resources 107 includes other circuitry such as digital processing (DSP) circuitry, blocks of random access memory (BRAM), I/O circuitry, data transceivers, interface elements, system monitoring circuitry, Ethernet Media Access Controller (MAC) circuitry, or the like.

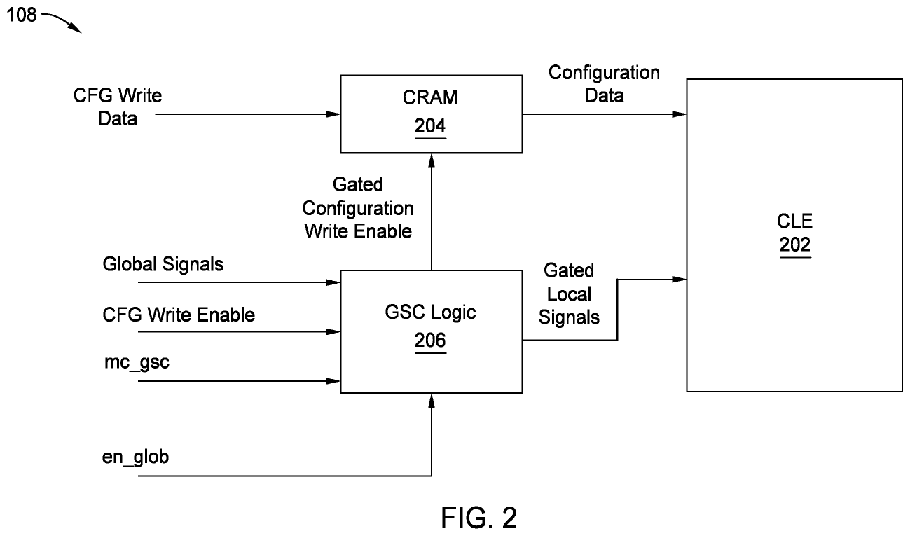

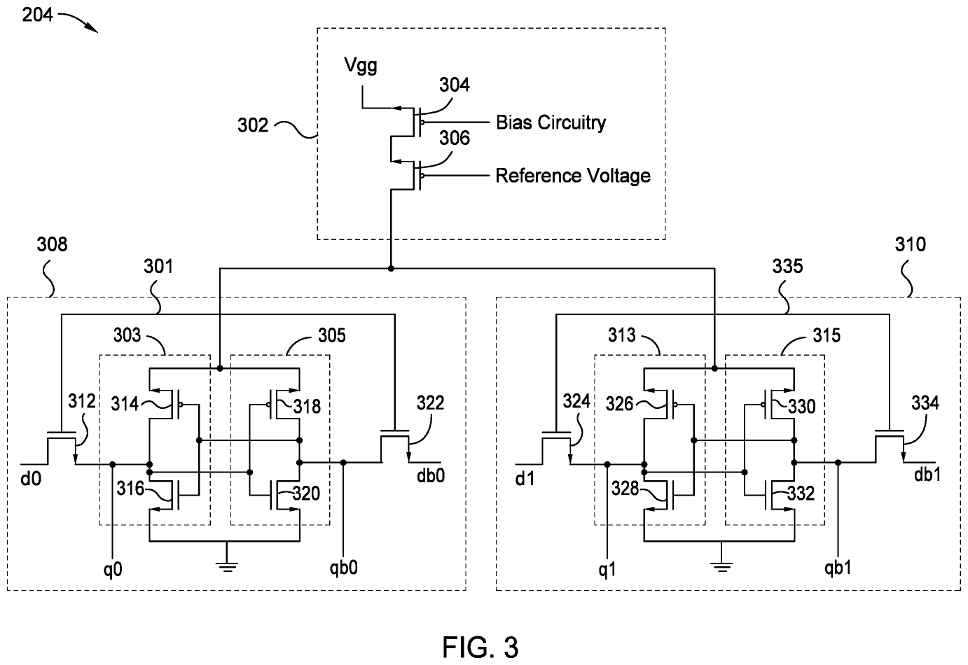

FIG. 2 illustrates a configurable logic block (CLB) 108 according to one or more examples. The CLB 108 includes a configurable logic element (CLE) 202. In one example, the CLB 108 comprises configuration a configuration random access memory (CRAM) device 204 and gating logic circuitry (GSC Logic) 206. The CRAM device 204 will be described in more detail in FIG. 3 below. In one example, the gating logic circuitry (GSC Logic) 206, receives a local enable signal, such as mc_gsc, that controls the operation of the gating logic circuitry 206. Accordingly, gated local signals are provided to the CLE 202 to control the operation of the CLE 202, as well as a gated configuration write enable signal which enables the ability to write to the CRAM device 204. The CRAM device 204 receives configuration (CFG) write data to be written to memory in response to the gated configuration write enable signal. The configuration data stored in the CRAM device 204 enables the operation of the CLE 202.

The gating logic circuitry 206 is coupled to receive the global signals, a configuration write enable signal (CFG write enable), and the local enable signal mc_gsc. It should be noted that the local enable signal mc_gsc could be a memory bit stored in the configuration memory. The gating logic circuitry 206 also receives a global enable (en_glob) signal.

FIG. 3 illustrates a CRAM device 204 according to one or more examples. In one example, the CRAM device 204 includes two bit cells. For example, the CRAM device 204 includes a first bit cell 308 and a second bit cell 310. The first bit cell 308 and the second bit cell 310 are coupled to header circuitry 302. Although the CRAM device 204 is described as having two bit cells, the CRAM device 204 may include any quantity of bit cells.

The first bit cell 308 includes a word line (or address line) 301, a first inverter 303 comprising transistors 314 and 316, and a second inverter 305 comprising transistors 318 and 320. Each inverter is formed by a p-type transistor coupled to an n-type transistor. For example, the first inverter is formed by transistors 314 and 316. The second inverter is formed by transistors 318 and 320. The first inverter 303 is formed by coupling the drain of transistor 314 to the drain of transistor 316. The source of transistor 314 is coupled to an output of the header circuitry 302. The source of transistor 316 is coupled to a reference voltage (i.e., ground). Therefore, transistor 314 operates as a pull-up transistor and transistor 316 operates as a pass-gate transistor. The second inverter 305 is formed by coupling the drain of transistor 318 to the drain of transistor 320. The source of transistor 318 is coupled to an output of the header circuitry 302. The source of transistor 320 is coupled to a reference voltage (i.e., ground). Therefore, transistor 318 operates as a pull-up transistor and transistor 320 operates as a pass-gate transistor. The header circuitry 302 will be discussed in more detail below.

As described above, in one example, the CRAM device 204 is embedded in an IC, such as an FPGA. Therefore, the CRAM device 204 is directly connected to storage nodes of the FPGA. The storage nodes are used to cross-couple the first inverter 303 and the second inverter 305 in order to store data contained in the CRAM device 204. A first storage node q0 is coupled to the gates of transistors 318 and 320 while a first inverse storage node qb0 is coupled to the gates of transistors 314 and 316. It should be noted that the first storage node q is an example of a storage node, and the first inverse storage node qb is an example of an inverse storage node. The first storage node q0 is also coupled to the drains of transistors 314 and 316 while the first inverse storage node qb0 is coupled to the drains of transistors 318 and 320.

The word line 301 is used to couple transistors 312 and 322 of the first bit cell 308. In one example, transistors 312 and 322 are n-type transistors. The word line 301 connects the gates of transistors 312 and 322. Transistors 312 and 322 are used to control access to the first storage node q0 and the first inverse storage node qb0, respectively, by the data or bitline nodes. The CRAM device 204 is directly connected to data nodes of neighboring circuitry of an FPGA because it is embedded in the FPGA. The data nodes are used to both read and write data to respective data nodes. A first data node do is coupled to the drain of transistor 312. First storage node q0 is coupled to the source of transistor 312. A first inverse data node db0 is coupled to the source of transistor 322. First inverse storage node qb0 is coupled to the drain of transistor 322. It should be noted that first data node do is an example of a data node, and that first inverse data node db0 is an example of an inverse data node. In summary, transistors 314, 318 are p-type transistors while transistors 312, 316, 320, and 322 are n-type transistors.

The second bit cell 310 includes a word line (or address line) 335, a third inverter 313 comprising transistors 326 and 328, and a fourth inverter 315 comprising transistors 330 and 332. Each inverter is formed by a p-type transistor coupled to an n-type transistor. For example, the third inverter 313 is formed by transistors 326 and 328. The fourth inverter 315 is formed by transistors 330 and 332. The third inverter 313 is formed by coupling the drain of transistor 326 to the drain of transistor 328. The source of transistor 326 is coupled to an output of the header circuitry 302. The source of transistor 328 is coupled to a reference voltage (i.e., ground). Therefore, transistor 326 operates as a pull-up transistor and transistor 328 operates as a pull-down transistor. The fourth inverter 315 is formed by coupling the drain of transistor 330 to the drain of transistor 332. The source of transistor 330 is coupled to an output of the header circuitry 302. The source of transistor 332 is coupled to a reference voltage (i.e., ground). Therefore, transistor 330 operates as a pull-up transistor and transistor 332 operates as a pull-down transistor. The header circuitry 302 will be discussed in more detail below

For the same reasons described above, the CRAM device 204 is directly connected a second storage node q0 and a second inverse storage node qb1. The second storage node q1 and the second inverse storage node qb1 are used to cross-couple the third inverter 313 and the fourth inverter 315 in order to store data contained in the CRAM device 204. Stated differently, the second storage node q1 is coupled to the gates of transistors 330 and 332 while the second inverse storage node qb1 is coupled to the gates of transistors 326 and 328. The second storage node q1 is also coupled to the drains of transistors 326 and 328 while the second inverse storage node qb1 is coupled to the drains of transistors 330 and 332.

The word line 335 is used to couple transistors 324 and 334 of the second bit cell 310. In one example, transistors 324 and 334 are n-type transistors. Word line 335 connects the gates of transistors 324 and 334. Transistors 324 and 334 are used to control access to nodes q and qb, respectively, by data or bitline nodes. In one example, because the CRAM device 204 is embedded in an FPGA neighboring bit cells share a common data node and a common inverse data node. A second data node d1 is coupled to the drain of transistor 324. The second storage node q1 is coupled to the source of transistor 324. The second inverse data node db1 is coupled to the source of transistor 334. The second inverse storage node qb1 is coupled to the drain of transistor 334.

To mitigate the issues that arise with the shift to advanced technology beyond the 7 nm node, the first bit cell 308 and the second bit cell 310 are coupled to the header circuitry 302. The header circuitry 302 includes a first header transistor 304 and a second header transistor 306. In one example, the first header transistor 304 and the second header transistor 306 are both p-type transistors. The source of the first header transistor 304 is coupled to a voltage source Vgg. The drain of the first header transistor 304 is coupled to the source of the second header transistor 306. The gate of the first header transistor 304 is coupled to bias circuitry. The drain of the second header transistor 306 is coupled to the sources of transistors 314, 318, 326, and 330. The gate of the second header transistor 306 is coupled to reference voltage (e.g., ground). Therefore, in the illustrated example, the CRAM device 204 is an 8-T memory cell.

As described above, the CRAM device 204 requires a high write margin. However, due to the design constraints of advanced technology beyond the 7 nm node, it is not possible to use weaker pull-up transistors and/or use wider/stronger pass-gate transistors. Therefore, the biasing circuitry outputs a bias voltage that is used to control to control the voltage supplied to the gate of the first header transistor 304, while the second header transistor 306 is always on because it is coupled to the reference voltage. Advantageously this increases the alpha ratio between the pull-up transistor and the pass gate-transistor, thus allowing for a wider write operation margin, and reduces both bit line and cell leakage. Furthermore, the reduction in bit line and cell leakage allows the CRAM device 204 to support products that require higher operating temperatures, which cause higher bit line and cell leakage. For example, the CRAM device 204 is able support an automobile that operate in the 125° C. spec.

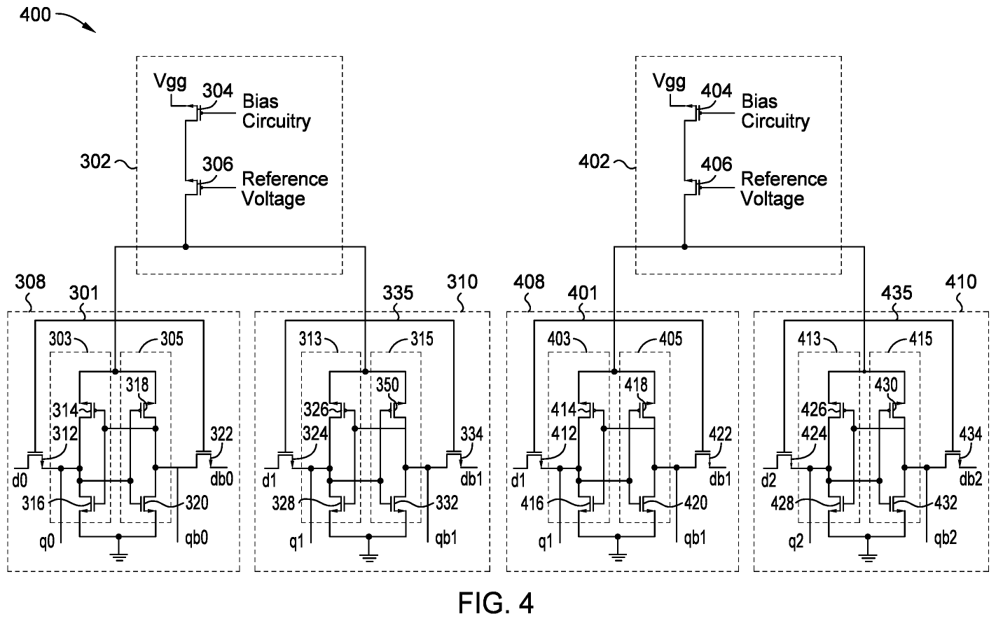

FIG. 4 illustrates a CRAM device 400 according to one or more examples. The CRAM device 400 is similar to CRAM device 204 except that the CRAM device 400 includes two additional bit cells. The CRAM device 400 includes a third bit cell 408 and a fourth bit cell 410. The third bit cell 408 and the fourth bit cell 410 are both coupled to a header circuitry 402.

The third bit cell 408 includes a word line (or address line) 401, a fifth inverter 403 comprising transistors 414 and 416, and a sixth inverter 405 comprising transistors 418 and 420. The fifth inverter 403 is formed by coupling the drain of transistor 414 to the drain of transistor 416. The source of transistor 414 is coupled to an output of the header circuitry 402. The source of transistor 416 is coupled to a reference voltage (i.e., ground). Therefore, transistor 414 operates as a pull-up transistor and transistor 416 operates as a pass-gate transistor. The sixth inverter 405 is formed by coupling the drain of transistor 418 to the drain of transistor 420. The source of transistor 418 is coupled to an output of the header circuitry 402. The source of transistor 420 is coupled to a reference voltage (i.e., ground). Therefore, transistor 418 operates as a pull-up transistor and transistor 420 operates as a pass-gate transistor.

Storage nodes are used to cross-couple the fifth inverter 403 and the sixth inverter 405 in order to store data contained in the CRAM device 400. The second storage node q1 is coupled to the gates of transistors 418 and 420 while the second inverse storage node qb1 is coupled to the gates of transistors 414 and 416. The second storage node q1 is also coupled to the drains of transistors 414 and 416 while the second inverse storage node qb1 is coupled to the drains of transistors 418 and 420.

The word line 401 is used to couple transistors 412 and 422 of the third bit cell 408. In one example, transistors 412 and 422 are n-type transistors. Word line 401 connects the gates of transistors 412 and 422. Transistors 412 and 422 are used to control access to the second storage node q1 and the second inverse storage node qb1. Second data node d1 is coupled to the drain of transistor 412. The second storage node q1 is coupled to the source of transistor 412. Second inverse data node db1 is coupled to the source of transistor 422. The second inverse storage node qb1 is coupled to the drain of transistor 422. Stated differently, adjacent (neighboring) bit cells can share common data and storage nodes

The fourth bit cell 410 includes a word line 435, a seventh inverter 413 comprising transistors 426 and 428, and an eighth inverter 415 comprising transistors 430 and 432. The seventh inverter 413 is formed by coupling the drain of transistor 426 to the drain of transistor 428. The source of transistor 426 is coupled to an output of the header circuitry 402. The source of transistor 428 is coupled to a reference voltage (i.e., ground). Therefore, transistor 426 operates as a pull-up transistor and transistor 428 operates as a pass-gate transistor. The eighth inverter 415 is formed by coupling the drain of transistor 430 to the drain of transistor 432. The source of transistor 430 is coupled to an output of the header circuitry 402. The source of transistor 432 is coupled to a reference voltage (i.e., ground). Therefore, transistor 430 operates as a pull-up transistor and transistor 432 operates as a pass-gate transistor.

Storage nodes are used to cross-couple the seventh inverter 413 and the eighth inverter 415. Stated differently, a third storage node q2 is coupled to the gates of transistors 430 and 432 while a third inverse storage node qb2 is coupled to the gates of transistors 426 and 428. The third storage node q2 is also coupled to the drains of transistors 426 and 428 while the third inverse storage node qb2 is coupled to the drains of transistors 430 and 432.

The word line 435 is used to couple transistors 424 and 434 of the fourth bit cell 410. In one example, transistors 424 and 434 are n-type transistors. Word line 435 connects the gates of transistors 424 and 434. Transistors 424 and 434 are used to control access to nodes q and qb. A third data node d2 is coupled to the drain of transistor 424. The third storage node q2 is coupled to the source of transistor 424. The third inverse data node db2 is coupled to the source of transistor 434. The third inverse storage node qb2 is coupled to the drain of transistor 434.

The header circuitry 402 includes a third header transistor 404 and a fourth header transistor 406. In one example, the third header transistor 404 and the fourth header transistor 406 are both p-type transistors. The source of the third header transistor 404 is coupled to the voltage source Vgg. The drain of the third header transistor 404 is coupled to the source of the fourth header transistor 406. The gate of the third header transistor 404 is coupled to the bias circuitry. The drain of the fourth header transistor 406 is coupled to the sources of transistors 314, 318, 326, and 330. The gate of the fourth header transistor 406 is coupled to reference voltage (e.g., ground). Although FIG. 4 illustrates one header circuitry controlling a pair (i.e., 2) bit cells, a single header circuitry may be used to control more than 2 bit cells.

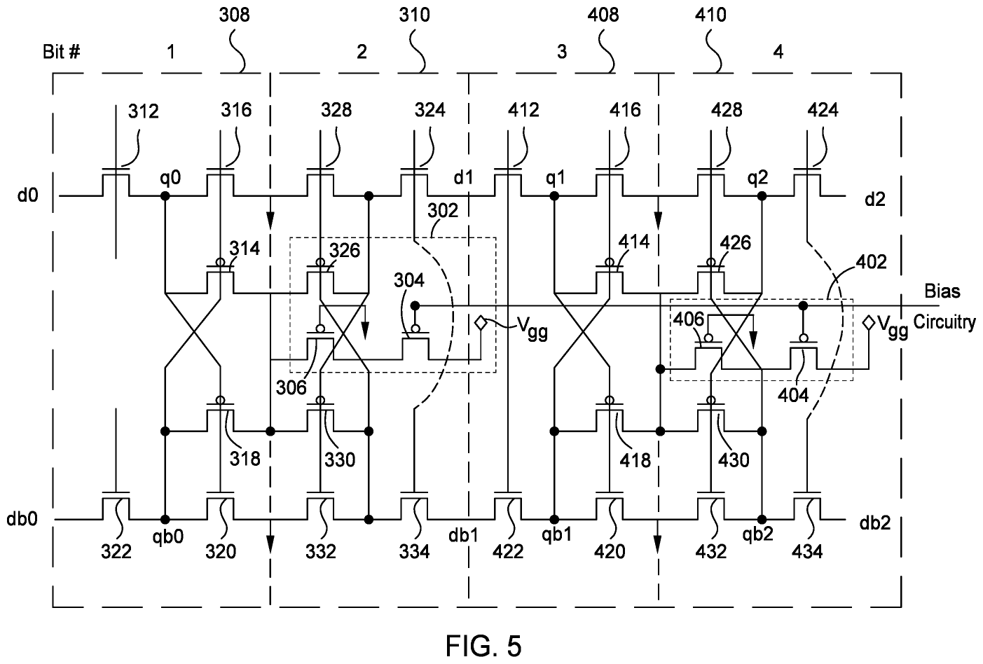

FIG. 5 illustrates a schematic implementation of the CRAM device 400 according to one or more examples. FIG. 5 is described with reference to FIG. 4. The CRAM device 400 includes each of the transistors arranged in rows. Each row of transistors includes transistors of the same type. For example a first row of n-type transistors includes transistors 312, 316, 324, 328, 324, 412, 416, 428, 424. A second row of n-type transistor includes transistors 320, 322, 332, 334, 420, 422, 432, 434. A first row of p-type transistors includes transistors 314, 326, 414, and 426. A second row of p-type transistors includes transistors 318, 330, 418, and 430. As described above, because the header circuitry 302 and the header circuitry 402 are each coupled to two corresponding bit cells, and therefore, both header circuitries are implemented as an additional row of transistors. For example an additional row of p-type transistors includes the first header transistor 304, the second header transistor 306, the third header transistor 404, and the fourth header transistor 406. Advantageously, this minimizes the overall area increase of the CRAM device 400 from 6-T to 8-T.

Although header circuitry 302 and header circuitry 402 are shown as including two header transistors, header circuitry 302 and header circuitry 402 may include more than two header transistors.

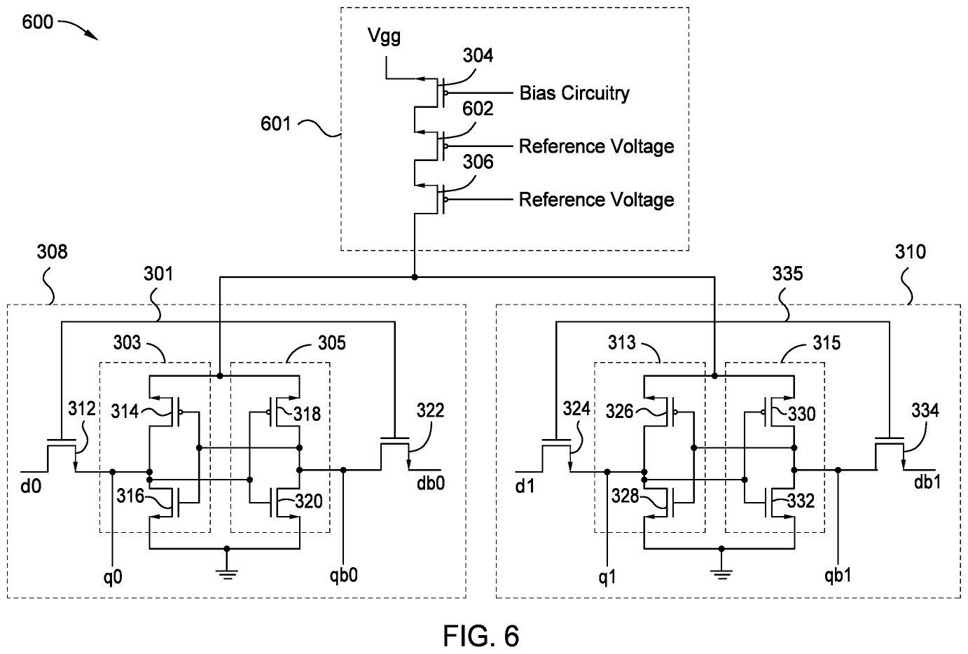

FIG. 6 illustrates a schematic implementation of a CRAM device 600 according to one or more examples. In one example, header circuitry 601 includes a third header transistor 602. Third header transistor 602 is a p-type transistor positioned between the first header transistor 304 and the second header transistor 306. The source of third header transistor 602 is coupled to the drain of first header transistor 304. The drain of third header transistor 602 is coupled to source of the second header transistor 306. The gate of the third header transistor 602 is coupled to the reference voltage. The number of header transistors is not limited by this application. For example a fourth header transistor (not shown) may be added between the third header transistor 602 and the second header transistor 306 with the source of the fourth header transistor coupled to the drain of the third header transistor 602, the drain of the fourth header transistor coupled to the source of the second header transistor 306, and the gate of the fourth header transistor coupled to the reference voltage.

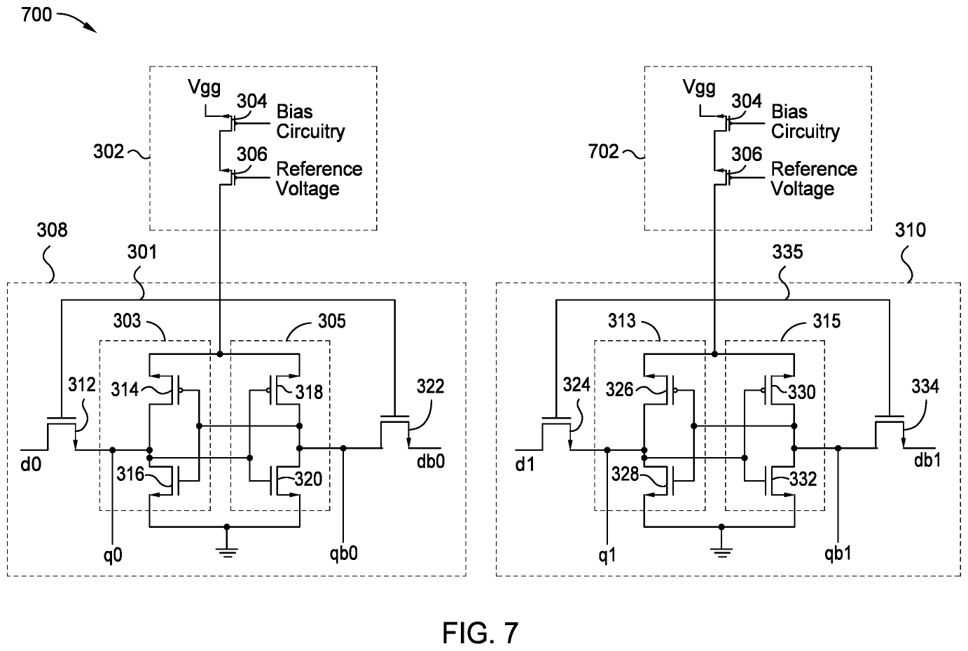

Although the CRAM device 400 is illustrated as having one header circuitry coupled to a pair bit cells, this is for example purposes only. In one example, each bit cell is coupled to an individual header circuitry. FIG. 7 illustrates a schematic implementation of a CRAM device 700 according to one or more examples. In one example, the CRAM device 700 includes header circuitry 302 coupled to the first bit cell 308 and header circuitry 702 coupled to the second bit cell. Stated differently, here, each bit cell is coupled to an individual header circuitry.

What is claimed is:

1. A memory device comprising:
a first bit cell comprising a first inverter, the first inverter comprising a p-type transistor coupled to an n-type transistor; and
header circuitry coupled to the first inverter and comprising a first header transistor and a second header transistor, the first header transistor having a gate configured to receive a bias voltage, the second header transistor having a gate configured to receive a reference voltage.

2. The memory device of claim 1, wherein the first header transistor and the second header transistor are p-type transistors, and wherein a drain of the first header transistor is coupled to a source of the second header transistor.

3. The memory device of claim 1, wherein the header circuitry is coupled to a source of the p-type transistor of the first inverter.

4. The memory device of claim 1, wherein the first bit cell further comprises a second inverter comprising a p-type transistor coupled to an n-type transistor.

5. The memory device of claim 4, wherein the first inverter and the second inverter are cross-coupled by a storage node and an inverse storage node.

6. The memory device of claim 4, wherein the header circuitry is coupled to a source of the p-type transistor of the first inverter and a source of the p-type transistor of the second inverter.

7. The memory device of claim 1, further comprising a second bit cell coupled to the header circuitry.

8. The memory device of claim 7, wherein the second bit cell comprises a third inverter comprising a p-type transistor coupled to an n-type transistor, and a drain of the p-type transistor of the third inverter coupled to the header circuitry.

9. The memory device of claim 8, wherein the memory device is embedded in a field programmable gate array (FPGA).

10. The memory device of claim 9, wherein the first bit cell and the second bit cell share a common data node and inverse data node.

11. A memory device comprising:
first header circuitry comprising a first header transistor and a second header transistor, the first header transistor having a gate configured to receive a bias voltage, the second header transistor having a gate configured to receive a reference voltage;
second header circuitry comprising a third header transistor and a fourth header transistor, the third header transistor having a gate configured to receive the bias voltage, the fourth header transistor having a gate configured to receive the reference voltage;
a first bit cell and a second bit cell coupled to the first header circuitry; and
a third bit cell and a fourth bit cell coupled to the second header circuitry.

12. The memory device of claim 11, wherein the first header transistor, the second header transistor, the third header transistor, and the fourth header transistor are p-type transistors.

13. The memory device of claim 11, wherein a drain of the first header transistor is coupled to a source of the second header transistor, and a drain of the third header transistor is coupled to a source of the fourth header transistor.

14. The memory device of claim 11, wherein:
the first bit cell comprises:
a first inverter comprising a p-type transistor coupled to an n-type transistor; and
a second inverter comprising a p-type transistor coupled to an n-type transistor;
the second bit cell comprises:
a third inverter comprising a p-type transistor coupled to an n-type transistor; and
a fourth inverter comprising a p-type transistor coupled to an n-type transistor;
the third bit cell comprises:
a fifth inverter comprising a p-type transistor coupled to an n-type transistor; and
a sixth inverter comprising a p-type transistor coupled to an n-type transistor; and
the fourth bit cell comprises:
a seventh inverter comprising a p-type transistor coupled to an n-type transistor; and
an eighth inverter comprising a p-type transistor coupled to an n-type transistor.

15. The memory device of claim 14, wherein:
the first header circuitry is coupled to a source of the p-type transistor of the first inverter, a source of the p-type transistor of the second inverter, a source of the p-type transistor of the third inverter, and a source of the p-type transistor of the fourth inverter; and
the second header circuitry is coupled to a source of the p-type transistor of the fifth inverter, a source of the p-type transistor of the sixth inverter, a source of the p-type transistor of the seventh inverter, and a source of the p-type transistor of the eighth inverter.

16. The memory device of claim 14, wherein:
the first inverter and the second inverter are cross-coupled by a first storage node and a first inverse storage node;
the third inverter and the fourth inverter are cross-coupled by a second storage node and a second inverse storage node;
the fifth inverter and the sixth inverter are cross-coupled by the second storage node and the second inverse storage node; and
the seventh inverter and the eighth inverter are cross-coupled by a third storage node and a third inverse storage node.

17. The memory device of claim 11, wherein the memory device is embedded in an field programmable gate array (FPGA).

18. The memory device of claim 17, wherein neighboring bit cells share a common data node and an inverse data node.

19. A memory device comprising:
a first bit cell comprising a first inverter cross-coupled to a second inverter by a first storage node and a first inverse storage node; and
a first header circuitry comprising a first header transistor and a second header transistor; the first header transistor having a gate configured to receive a bias voltage, the second header transistor having a gate configured to receive a reference voltage, the first header circuitry coupled to the first inverter and the second inverter.

20. The memory device of claim 16, further comprising:
a second bit cell comprising a third inverter cross-coupled to a fourth inverter, the third inverter and the fourth inverter cross-coupled by a second storage node and a second inverse storage node, wherein the first header circuitry is coupled to the third inverter and the fourth inverter.
